(19) United States
(12) Patent Application Publication
(10) Pub. No.: US 2024/0332318 A1
(43) Pub. Date: Oct. 3, 2024

(54) ARRAY SUBSTRATE AND DISPLAY DEVICE

(71) Applicant: Japan Display Inc., Tokyo (JP)

(72) Inventors: Akihiko SAITOH, Tokyo (JP); Hiroyuki ABE, Tokyo (JP)

(73) Assignee: Japan Display Inc., Tokyo (JP)

(21) Appl. No.: 18/594,349

(22) Filed: Mar. 4, 2024

(30) Foreign Application Priority Data
Mar. 29, 2023 (JP) 2023-053351

(51) Int. Cl. H01L 27/12; G02F 1/1362; G02F 1/1368

(52) U.S. Cl. CPC H01L 27/1244; G02F 1/136209; G02F 1/136286; G02F 1/1368

(57) ABSTRACT

According to one embodiment, an array substrate includes signal lines and a switch circuit. The signal lines include first and second signal lines. The switch circuit includes a circuit unit including first and second transistors, a first input line, first and second select lines, a first output line which intersects with the first select line, and a second output line which intersects with the first select line. A first intersection of the first output line which intersects with the first select line and a second intersection of the second output line which intersects with the first select line are formed in different layers.

### CROSS-REFERENCE TO RELATED APPLICATIONS

This application is based upon and claims the benefit of priority from Japanese Patent Application No. 2023-053351, filed Mar. 29, 2023, the entire contents of which are incorporated herein by reference.

### FIELD

Embodiments described herein relate generally to an array substrate and a display device.

### BACKGROUND

In general, each display device comprises a pixel electrode provided in each of a plurality of pixels, a pixel transistor connected to the pixel electrode, and a signal line which supplies a video signal to a pixel circuit. A switch circuit which selectively supplies a video signal to the signal line is provided in a surrounding area around a display area.

In recent years, the definition of pixels has been increased. Accordingly, the layout of circuits provided in the surrounding area also needs to be efficient.

### BRIEF DESCRIPTION OF THE DRAWINGS

FIG. 1 is a diagram showing a configuration example of a display device according to an embodiment.

FIG. 2 is a diagram showing an example of an equivalent circuit which could be applied to a subpixel.

FIG. 3 is a schematic cross-sectional view of the display device in an active area.

FIG. 4 is a schematic plan view of an array substrate in the active area.

FIG. 5 is a diagram showing an example of the configuration of each circuit unit included in a switch circuit.

FIG. 6 is a schematic plan view showing an example of a configuration which could be applied to the circuit units.

FIG. 7 is a plan view in which elements related to a first transistor and a second transistor are extracted from the circuit units shown in FIG. 6.

FIG. 8 is a plan view in which elements related to a third transistor and a fourth transistor are extracted from the circuit units shown in FIG. 6.

FIG. 9 is a schematic cross-sectional view showing the connection structure between the first transistor and a first signal line.

FIG. 10 is a schematic cross-sectional view showing the connection structure between the second transistor and a second signal line.

FIG. 11 is a schematic cross-sectional view showing the connection structure between the third transistor and a third signal line.

FIG. 12 is a schematic plan view in which the vicinity of a first select line in FIG. 6 is enlarged.

### DETAILED DESCRIPTION

In general, according to one embodiment, an array substrate comprises a plurality of signal lines provided in an active area, and a switch circuit provided in a surrounding area around the active area and connected to the signal lines. The signal lines include a first signal line and a second signal line. The switch circuit includes a circuit unit including a first transistor and a second transistor, a first input line connected to the first transistor and the second transistor, a first select line which is provided between the circuit unit and the active area and supplies a first select signal for turning the first transistor on, a second select line which supplies a second select signal for turning the second transistor on, a first output line which connects the first transistor and the first signal line to each other and intersects with the first select line, and a second output line which connects the second transistor and the second signal line to each other and intersects with the first select line. Further, a first intersection of the first output line which intersects with the first select line and a second intersection of the second output line which intersects with the first select line are formed in different layers.

According to another embodiment, a display device comprises the array substrate. Further, the active area includes a plurality of pixel transistors connected to the signal lines, and a plurality of pixel electrodes connected to the pixel transistors, respectively.

The embodiments can provide an array substrate and a display device such that the layout of circuits provided in a surrounding area can be efficient.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The present embodiment discloses a liquid crystal display device and an array substrate provided in the liquid crystal display device as examples of display devices and array substrates. It should be noted that the configuration disclosed in the embodiment, particularly the circuit configuration for supplying signals to signal lines in an active area, can be applied to other types of display devices and electronic devices other than display devices. As electronic devices other than display devices, for example, a sensor in which a plurality of detection elements are provided in an active area is considered.

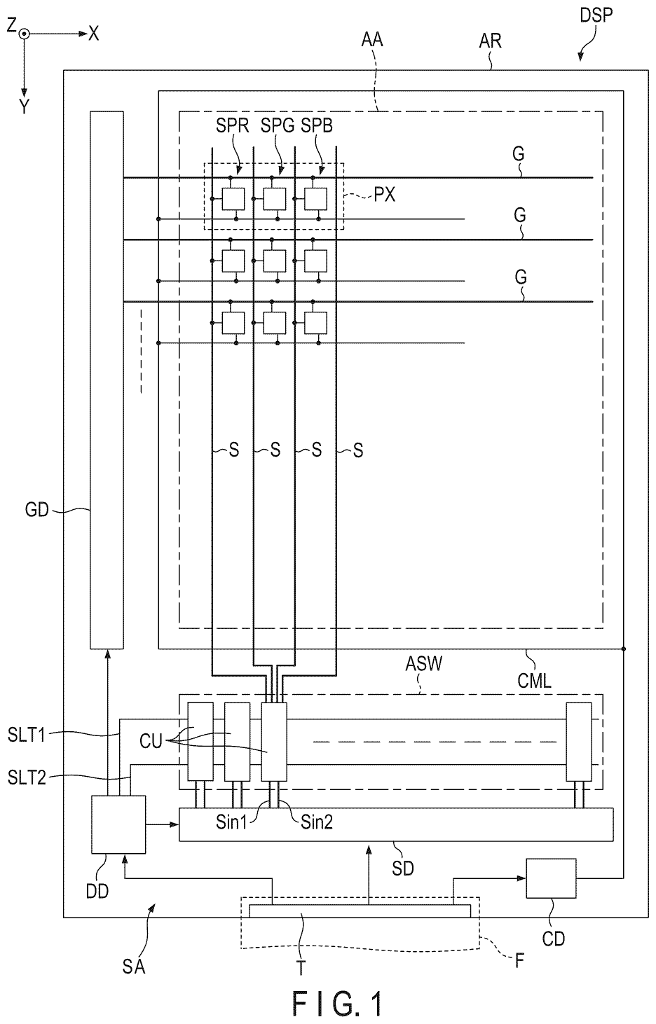

FIG. 1 is a diagram showing a configuration example of a liquid crystal display device DSP (hereinafter, simply referred to as a display device DSP) according to an embodiment. The display device DSP comprises an array substrate AR. In the example of FIG. 1, the array substrate AR is rectangular. However, the configuration is not limited to this example.

The array substrate AR comprises an active area AA (display area) including a plurality of pixels PX and a surrounding area SA around the active area AA. For example, each pixel PX includes a red subpixel SPR, a green subpixel SPG and a blue subpixel SPB. The configuration is not limited to this example. Each pixel PX may include a subpixel which exhibits another color such as white.

The array substrate AR further comprises a plurality of scanning lines G and a plurality of signal lines S. The scanning lines G extend in a first direction X in the active area AA and are arranged in a second direction Y. The signal lines S extend in the second direction Y in the active area AA and are arranged in the first direction X.

A terminal portion T is provided in the surrounding area SA. A flexible printed circuit F is connected to the terminal T via, for example, a conductive adhesive. The voltage and signals necessary for the drive of the array substrate AR are input via the flexible printed circuit F and the terminal portion T.

The array substrate AR comprises a drive element DD, a scanning line drive circuit GD, a signal line drive circuit SD, a switch circuit ASW (selector) and a common voltage drive circuit CD. All of these elements are provided in the surrounding area SA. It should be noted that, for example, the drive element DD and the common voltage drive circuit CD may be mounted in the flexible printed circuit F.

The drive element DD is, for example, an IC, and controls the scanning line drive circuit GD, the signal line drive circuit SD, the switch circuit ASW and the common voltage drive circuit CD based on control signals such as a clock signal and a timing signal input to the terminal portion T.

The common voltage drive circuit CD applies common voltage to a common voltage line CML. The common voltage line CML is provided in, for example, the surrounding area SA and surrounds the active area AA. The scanning line drive circuit GD supplies a scanning signal to each scanning line G by time division.

The drive element DD and the switch circuit ASW are connected to each other by a first select line SLT1 and a second select line SLT2. The drive element DD supplies a select signal to the first select line SLT1 and the second select line SLT2 by time division.

The switch circuit ASW comprises a plurality of circuit units CU arranged in the first direction X. In the embodiment, each circuit unit CU is connected to the signal line drive circuit SD via a first input line Sin1 and a second input line Sin2. Each circuit unit CU is connected to four signal lines S.

The signal line drive circuit SD outputs video signals to the input lines Sin1 and Sin2. Each circuit unit CU switches the signal line S to which these video signals should be output based on the select signals supplied to the select lines SLT1 and SLT2.

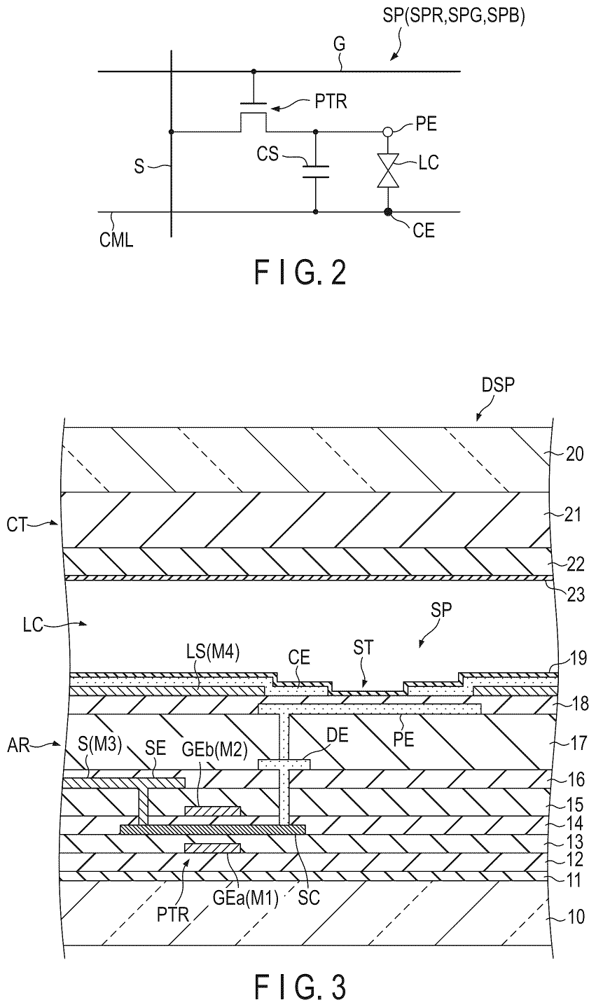

FIG. 2 is a diagram showing an example of an equivalent circuit which could be applied to a subpixel SP (SPR, SPG or SPB). A subpixel SP comprises a pixel transistor PTR and a pixel electrode PE. The source electrode of the pixel transistor PTR is connected to a signal line S. The gate electrode is connected to a scanning line G. The drain electrode is connected to a pixel electrode PE. The common voltage of the common voltage line CML is applied to a common electrode CE. Storage capacitance CS is formed between the pixel electrode PE and the common electrode CE.

When a scanning signal is supplied to the scanning line G, voltage based on the video signal of the signal line S is applied to the pixel electrode PE. Thus, a potential difference is generated between the common electrode CE and the pixel electrode PE. An electric field based on this potential difference affects a liquid crystal layer LC provided in the display device DSP.

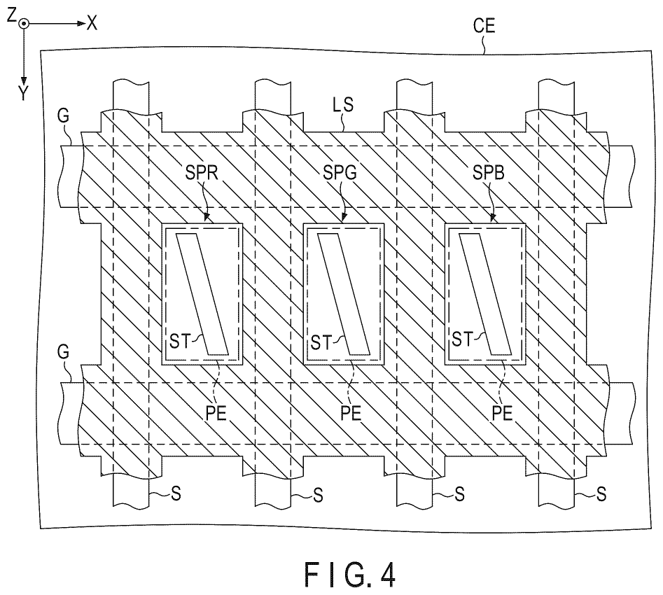

FIG. 3 is a schematic cross-sectional view of the display device DSP in the active area AA. The display device DSP comprises a counter-substrate CT in addition to the array substrate AR and liquid crystal layer LC described above. The counter-substrate CT faces the array substrate AR. The liquid crystal layer LC is sealed in between the array substrate AR and the counter-substrate CT.

In the example of FIG. 3, the array substrate AR comprises the signal line S, pixel transistor PTR, pixel electrode PE and common electrode CE described above. Further, the array substrate AR comprises an insulating substrate 10, insulating layers 11 to 18, an alignment film 19 and a light-shielding layer LS.

The pixel transistor PTR includes a semiconductor layer SC, a gate electrodes GEa and GEb, a source electrode SE and a drain electrode DE. The gate electrodes GEa and GEb are, for example, part of the scanning line G. The source electrode SE is, for example, part of the signal line S.

For the insulating substrate 10, for example, a transparent glass substrate or a resinous substrate can be used. Each of the insulating layers 11 to 16 and 18 is formed of an inorganic insulating material. The insulating layer 17 is formed of an organic insulating material. Each of the signal line S (source electrode SE), the scanning line G (the gate electrodes GEa and GEb) and the light-shielding layer LS is formed of a conductive metal material. The alignment film 19 is formed of an alignment film material such as polyimide. Each of the pixel electrode PE, the common electrode CE and the drain electrode DE is formed of a transparent conductive oxide such as indium tin oxide (ITO).

The insulating layer 11 covers the insulating substrate 10. The insulating layer 12 covers the insulating layer 11. The gate electrode GEa is provided on the insulating layer 12. The insulating layer 13 covers the gate electrode GEa and the insulating layer 12. The semiconductor layer SC is provided on the insulating layer 13. The insulating layer 14 covers the semiconductor layer SC and the insulating layer 13. The gate electrode GEb is provided on the insulating layer 14. Both the gate electrode GEa and the gate electrode GEb face the semiconductor layer SC.

The insulating layer 15 covers the gate electrode GEb and the insulating layer 14. The signal line S and the source electrode SE are provided on the insulating layer 15. The source electrode SE is in contact with the semiconductor layer SC through a contact hole which penetrates the insulating layers 14 and 15. The drain electrode DE is provided on the insulating layer 16. The drain electrode DE is in contact with the semiconductor layer SC through a contact hole which penetrates the insulating layers 14 to 16.

The insulating layer 17 covers the drain electrode DE and the insulating layer 16. The insulating layer 17 formed of an organic insulating material is sufficiently thicker than the other insulating layers 11 to 16 and 18 and planarizes the irregularities formed by the pixel transistor PTR.

The pixel electrode PE is provided on the insulating layer 17. The pixel electrode PE is in contact with the drain electrode DE through a contact hole which penetrates the insulating layer 17. The insulating layer 18 covers the pixel electrode PE and the insulating layer 17. The light-shielding layer LS is provided on the insulating layer 18. The common electrode CE covers the light-shielding layer LS. The alignment film 19 covers the common electrode CE. In the example of FIG. 3, the common electrode CE comprises a slit ST.

The counter-substrate CT comprises an insulating substrate 20, a color filter layer 21, an overcoat layer 22 and an alignment film 23. For the insulating substrate 20, for example, a transparent glass substrate or a resinous substrate can be used. The color filter layer 21 includes a red color filter provided in subpixel SPR, a green color filter provided in subpixel SPG and a blue color filter provided in subpixel SPB. The overcoat layer 22 is formed of, for example, a transparent resinous material and covers the color filter layer 21. The alignment film 23 is formed of an alignment film material such as polyimide and covers the overcoat layer 22. It should be noted that the color filter layer 21 may be a color filter on array (COA) provided in the array substrate AR. In the case of COA, for example, the color filter layer 21 can be provided between the insulating layer 16 and the insulating layer 17.

In the following explanation, the metal layer provided between the insulating layers 12 and 13 (in other words, the layer of the gate electrode GEa) is called a metal layer M1. The metal layer provided between the insulating layers 14 and 15 (in other words, the layer of the gate electrode GEb) is called a metal layer M2. The metal layer provided between the insulating layers 15 and 16 (in other words, the layer of the signal line S) is called a metal layer M3. The metal layer provided on the insulating layer 18 (in other words, the layer of the light-shielding layer LS) is called a metal layer M4.

FIG. 4 is a schematic plan view of the array substrate AR in the active area AA. In this figure, some of conductive elements which constitute subpixels SPR, SPG and SPB are shown, and the pixel transistor PTR is omitted.

As described above, the scanning lines G extend in the first direction X, and the signal lines S extend in the second direction Y. In the example of FIG. 4, both the scanning lines G and the signal lines S are linear. However, the configuration is not limited to this example. For example, the signal lines S may extend in the second direction Y with a curved shape.

The light-shielding layer LS overlaps the scanning lines G and the signal lines S. By this configuration, in the example of FIG. 4, the light-shielding layer LS has a grating shape so as to open in subpixels SPR, SPG and SPB. When the signal lines S are curved as described above, the light-shielding layer LS may be curved in a similar manner.

The light-shielding layer LS has a reflectance which is lower than the reflectances of the scanning lines G and the signal lines S. This configuration prevents the scanning lines G and the signal lines S from reflecting light. The light-shielding layer LS is connected to the common voltage line CML described above. Thus, the light-shielding layer LS also functions as lines which apply common voltage to the common electrode CE.

The common electrode CE comprises a slit ST in each of subpixels SPR, SPG and SPB. These slits ST overlap the pixel electrodes PE of subpixels SPR, SPG and SPB, respectively. An electric field formed between each pixel electrode PE and the common electrode CE affects the liquid crystal layer LC through the slit ST.

In the example of FIG. 4, each slit ST extends in a direction intersecting with the first direction X and the second direction Y. The shape of each slit ST is not limited to this example. Each slit ST may extend parallel to the second direction Y. A plurality of slits ST may be formed for each of subpixels SPR, SPG and SPB.

Now, this specification explains the configuration of the switch circuit ASW.

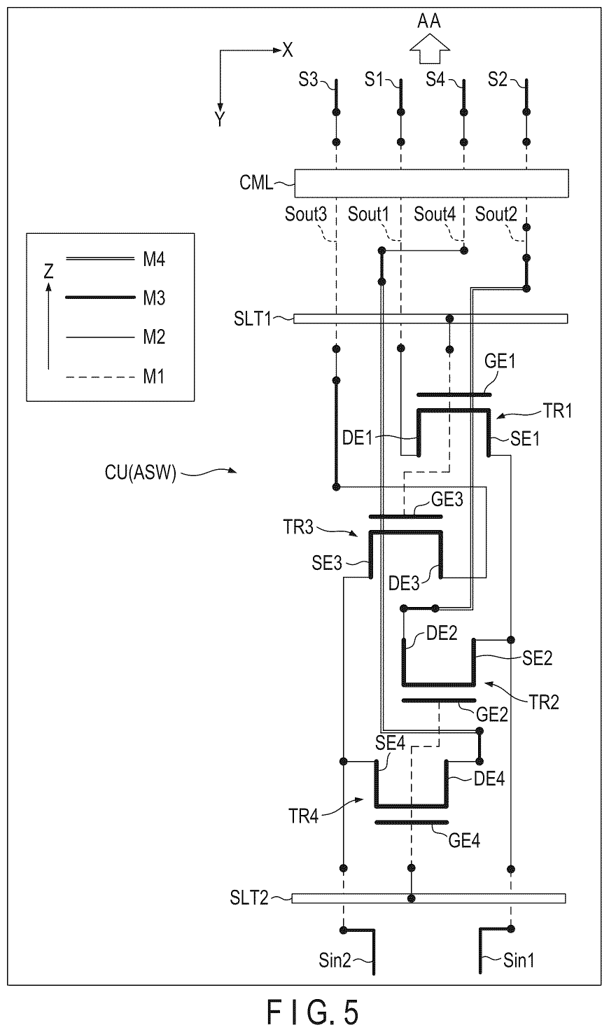

FIG. 5 is a diagram showing an example of the configuration of each circuit unit CU included in the switch circuit ASW. In this figure, the portions consisting of the metal layers M1 to M4 are indicated by different types of line segments in line with the explanatory notes shown in the rectangular frame. The active area AA is located on the upper side of the figure. The coordinate system of the first direction X and the second direction Y is added to roughly show the locational relationships of the elements. To simplify the figure, each line is shown by a line segment extending in the first direction X or the second direction Y. However, these segments do not necessarily define the accurate extension directions of the lines.

The first select line SLT1, second select line SLT2 and common voltage line CML shown in FIG. 1 as well extend in the first direction X. The common voltage line CML is located between the first select line SLT1 and the active area AA in the second direction Y. The first select line SLT1 is located between the second select line SLT2 and the common voltage line CML in the second direction Y.

The circuit unit CU includes a first transistor TR1, a second transistor TR2, a third transistor TR3 and a fourth transistor TR4. These transistors TR1 to TR4 are arranged in the second direction Y (the extension direction of the signal lines S) between the first select line SLT1 and the second select line SLT2. More specifically, the first transistor TR1, the third transistor TR3, the second transistor TR2 and the fourth transistor TR4 are arranged in this order from the first select line SLT1 side to the second select line SLT2 side.

The first select line SLT1 is connected to the gate electrode GE1 of the first transistor TR1 and the gate electrode GE3 of the third transistor TR3. The second select line SLT2 is connected to the gate electrode GE2 of the second transistor TR2 and the gate electrode GE4 of the fourth transistor TR4.

The first input line Sin1 and second input line Sin2 shown on the lower side of the figure are connected to the signal line drive circuit SD as shown in FIG. 1 as well. The first input line Sin1 is connected to the source electrode SE1 of the first transistor TR1 and the source electrode SE2 of the second transistor TR2. The second input line Sin2 is connected to the source electrode SE3 of the third transistor TR3 and the source electrode SE4 of the fourth transistor TR4.

The drain electrode DE1 of the first transistor TR1 is connected to a first output line Sout1. The drain electrode DE2 of the second transistor TR2 is connected to a second output line Sout2. The drain electrode DE3 of the third transistor TR3 is connected to a third output line Sout3. The drain electrode DE4 of the fourth transistor TR4 is connected to a fourth output line Sout4. These output lines Sout1 to Sout4 intersect with the first select line SLT1 and the common voltage line CML.

The signal lines S shown in FIG. 1 include a first signal line S1, a second signal line S2, a third signal line S3 and a fourth signal line S4. The first output line Sout1 is connected to the first signal line S1. The second output line Sout2 is connected to the second signal line S2. The third output line Sout3 is connected to the third signal line S3. The fourth output line Sout4 is connected to the fourth signal line S4.

A select signal is alternately supplied to the select lines STL1 and STL2. When a first select signal is supplied to the first select line SLT1, the transistors TR1 and TR3 are turned on. At this time, the video signal of the first input line Sin1 is output to the first signal line S1 via the first output line Sout1. The video signal of the second input line Sin2 is output to the third signal line S3 via the third output line Sout3.

When a second select signal is supplied to the second select line SLT2, the transistors TR2 and TR4 are turned on. At this time, the video signal of the first input line Sin1 is output to the second signal line S2 via the second output line Sout2. The video signal of the second input line Sin2 is output to the fourth signal line S4 via the fourth output line Sout4.

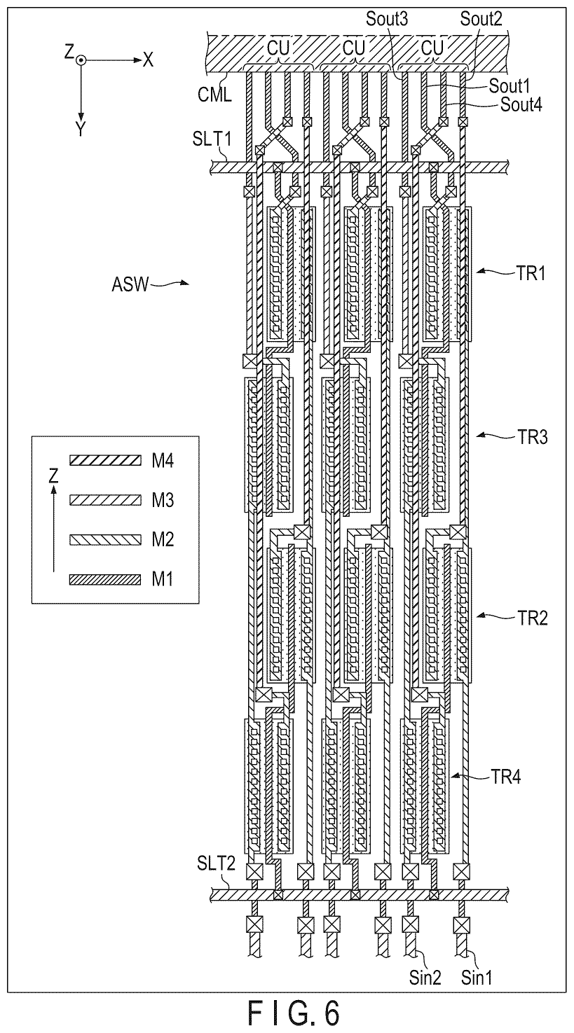

FIG. 6 is a schematic plan view showing an example of a configuration which could be applied to the circuit units CU. Here, three circuit units CU which are adjacent to each other in the first direction X are shown. In this figure, the portions consisting of the metal layers M1 to M4 are indicated by different types of diagonal patterns in line with the explanatory notes shown in the rectangular frame.

The circuit units CU comprise similar configurations. Specifically, in the switch circuit ASW, a plurality of first transistors TR1 are arranged in the first direction X. A plurality of second transistors TR2 are arranged in the first direction X. A plurality of third transistors TR3 are arranged in the first direction X. A plurality of fourth transistors TR4 are arranged in the first direction X.

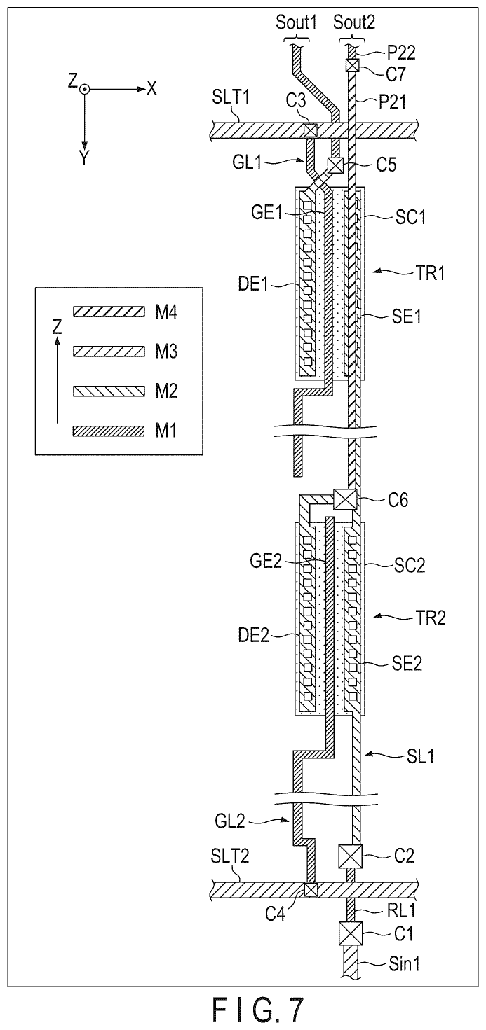

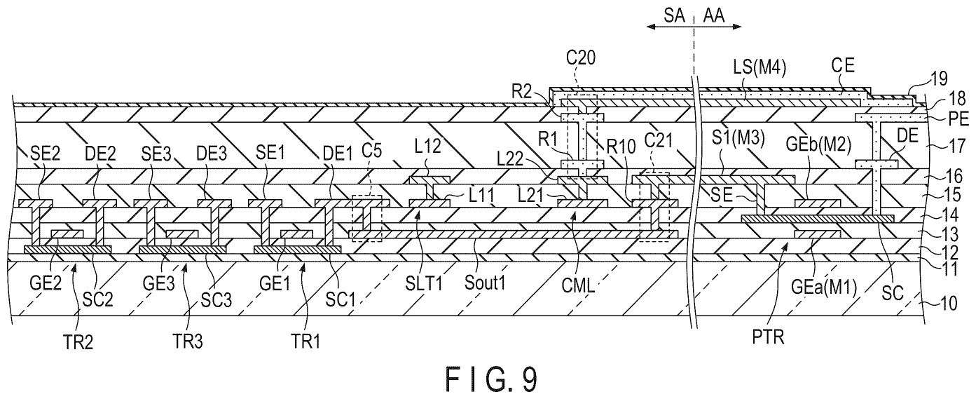

FIG. 7 is a plan view in which elements related to the first transistor TR1 and the second transistor TR2 are extracted from the circuit units CU shown in FIG. 6. Each of the select lines SLT1 and SLT2 comprises, for example, a stacked structure of the metal layers M2 and M3 (see FIG. 9). The first input line Sin1 is formed by, for example, the metal layer M3, and is connected to a relay line RL1 in a contact portion C1. It should be noted that the first input line Sin1 may be formed by the metal layer M2.

The relay line RL1 is connected to a source line SL1 in a contact portion C2. The relay line RL1 is formed by the metal layer M1. The source line SL1 is formed by the metal layer M2. The relay line RL1 intersects with the second select line SLT2 between the contact portions C1 and C2.

The first transistor TR1 comprises a semiconductor layer SC1. The second transistor TR2 comprises a semiconductor layer SC2. The semiconductor layers SC1 and SC2 are arranged in the second direction Y between the select lines SLT1 and SLT2.

The source line SL1 overlaps the semiconductor layers SC1 and SC2. Of the source line SL1, a portion which overlaps the semiconductor layer SC1 corresponds to the source electrode SE1. Of the source line SL1, a portion which overlaps the semiconductor layer SC2 corresponds to the source electrode SE2. The source electrodes SE1 and SE2 are in contact with the semiconductor layers SC1 and SC2, respectively.

Gate lines GL1 and GL2 formed by the metal layer M1 are provided between the select lines SLT1 and SLT2. The gate line GL1 is connected to the first select line SLT1 in a contact portion C3 and intersects with the semiconductor layer SC1. Of the gate line GL1, a portion which overlaps the semiconductor layer SC1 corresponds to the gate electrode GE1. The gate line GL2 is connected to the second select line SLT2 in a contact portion C4 and intersects with the semiconductor layer SC2. Of the gate line GL2, a portion which overlaps the semiconductor layer SC2 corresponds to the gate electrode GE2.

The drain electrode DE1 is formed by the metal layer M2 and is in contact with the semiconductor layer SC1. The first output line Sout1 is formed by the metal layer M1 and intersects with the first select line SLT1. The drain electrode DE1 and the first output line Sout1 are connected to each other in a contact portion C5.

The drain electrode DE2 is formed by the metal layer M2 and is in contact with the semiconductor layer SC2. The second output line Sout2 comprises a first portion P21 formed by the metal layer M4 and a second portion P22 formed by the metal layer M1. The drain electrode DE2 and the first portion P21 are connected to each other in a contact portion C6. The first portion P21 and the second portion P22 are connected to each other in a contact portion C7. The first portion P21 intersects with the first select line SLT1.

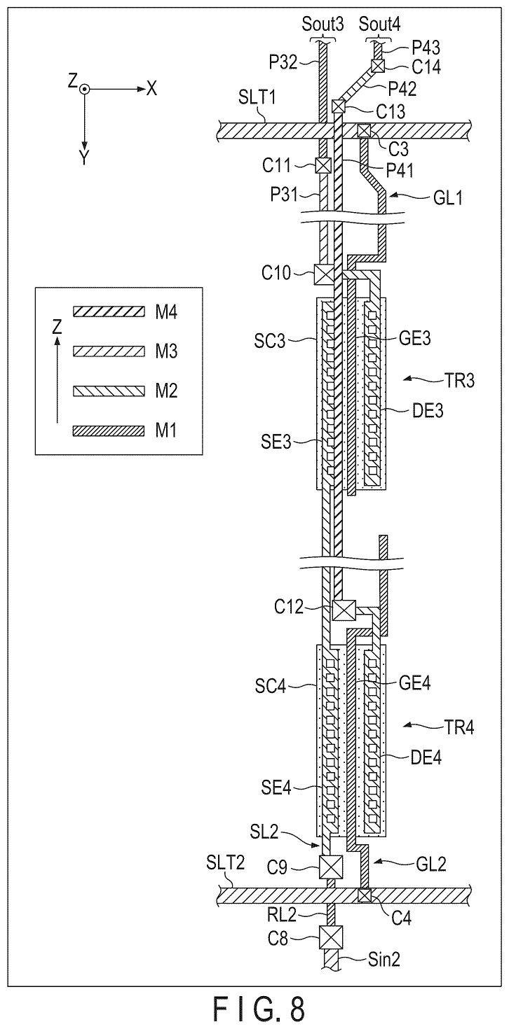

FIG. 8 is a plan view in which elements related to the third transistor TR3 and the fourth transistor TR4 are extracted from the circuit units CU shown in FIG. 6. The second input line Sin2 is formed by, for example, the metal layer M3 and is connected to a relay line RL2 in a contact portion C8. It should be noted that the second input line Sin2 may be formed by the metal layer M2.

The relay line RL2 is connected to the source line SL2 in a contact portion C9. The relay line RL2 is formed by the metal layer M1. The source line SL2 is formed by the metal layer M2. The relay line RL2 intersects with the second select line SLT2 between the contact portions C8 and C9.

The third transistor TR3 comprises a semiconductor layer SC3. The fourth transistor TR4 comprises a semiconductor layer SC4. The semiconductor layers SC3 and SC4 are arranged in the second direction Y between the select lines SLT1 and SLT2.

A source line SL2 overlaps the semiconductor layers SC3 and SC4. Of the source line SL2, a portion which overlaps the semiconductor layer SC3 corresponds to the source electrode SE3. Of the source line SL2, a portion which overlaps the semiconductor layer SC4 corresponds to the source electrode SE4. The source electrodes SE3 and SE4 are in contact with the semiconductor layers SC3 and SC4, respectively.

The gate line GL1 intersects with the semiconductor layer SC3. Of the gate line GL1, a portion which overlaps the semiconductor layer SC3 corresponds to the gate electrode GE3. The gate line GL2 intersects with the semiconductor layer SC4. Of the gate line GL2, a portion which overlaps the semiconductor layer SC4 corresponds to the gate electrode GE4.

The drain electrode DE3 is formed by the metal layer M2 and is in contact with the semiconductor layer SC3. The third output line Sout3 comprises a first portion P31 formed by the metal layer M3 and a second portion P32 formed by the metal layer M1. The drain electrode DE3 and the first portion P31 are connected to each other in a contact portion C10. The first portion P31 and the second portion P32 are connected to each other in a contact portion C11. The second portion P32 intersects with the first select line SLT1.

The drain electrode DE4 is formed by the metal layer M2 and is in contact with the semiconductor layer SC4. The fourth output line Sout4 comprises a first portion P41 formed by the metal layer M4, a second portion P42 formed by the metal layer M2 and a third portion P43 formed by the metal layer M1. The drain electrode DE4 and the first portion P41 are connected to each other in a contact portion C12. The first portion P41 and the second portion P42 are connected to each other in a contact portion C13. The second portion P42 and the third portion P43 are connected to each other in a contact portion C14. The first portion P41 intersects with the first select line SLT1.

FIG. 9 is a schematic cross-sectional view showing the connection structure between the first transistor TR1 and the first signal line S1. In FIG. 9, the fourth transistor TR4 is omitted. However, the structure of the fourth transistor TR4 is similar to the structures of the transistors TR1 to TR3.

In the example of FIG. 9, the first select line SLT1 comprises first and second layers L11 and L12 which are stacked in a third direction Z. The first layer L11 is provided on the insulating layer 14 and is covered with the insulating layer 15. The second layer L12 is provided on the insulating layer 15 and is covered with the insulating layer 16. The second layer L12 is connected to the first layer L11 through a contact hole which penetrates the insulating layer 15.

The common voltage line CML comprises first and second layers L21 and L22 which are stacked in the third direction Z. The first layer L21 is provided on the insulating layer 14 and is covered with the insulating layer 15. The second layer L22 is provided on the insulating layer 15 and is covered with the insulating layer 16. The second layer L22 is connected to the first layer L21 through a contact hole which penetrates the insulating layer 15.

The light-shielding layer LS overlaps the common voltage line CML in the surrounding area SA. The common voltage line CML and the light-shielding layer LS are connected to each other in a contact portion C20. In the example of FIG. 9, the contact portion C20 includes relay portions R1 and R2. The relay portion R1 is provided on the insulating layer 16 and is covered with the insulating layer 17. The relay portion R2 is provided on the insulating layer 17 and is covered with the insulating layer 18. The relay portion R1 is formed of the same conductive oxide as the drain electrode DE. The relay portion R2 is formed of the same conductive oxide as the pixel electrode PE.

The semiconductor layers SC1 to SC4 are provided on the insulating layer 11 and are covered with the insulating layer 12. For example, each of the semiconductor layers SC1 to SC4 is formed of a material which is different from that of the semiconductor layer SC of the pixel transistor TR. For example, each of the semiconductor layers SC1 to SC4 is formed of low-temperature polysilicon (LTPS), and the semiconductor layer SC is formed of an oxide semiconductor.

The gate electrodes GE1 to GE4 are provided on the insulating layer 12 and are covered with the insulating layer 13. The source electrodes SE1 to SE4 and the drain electrodes DE1 to DE4 are provided on the insulating layer 14 and are covered with the insulating layer 15. The source electrodes SE1 to SE4 are in contact with the semiconductor layers SC1 to SC4, respectively, through contact holes which penetrate the insulating layers 13 and 14. Further, the drain electrodes DE1 to DE4 are in contact with the semiconductor layers SC1 to SC4, respectively, through contact holes which penetrate the insulating layers 13 and 14.

The first output line Sout1 connected to the drain electrode DE1 in the contact portion C5 passes through the lower side of the first select line SLT1 and the common voltage line CML and is connected to the first signal line S1 in a contact portion C21. In the example of FIG. 9, the contact portion C21 includes a relay portion R10. The relay portion R10 is provided on the insulating layer 14 and is covered with the insulating layer 15. Thus, the relay portion R10 is formed by the metal layer M2.

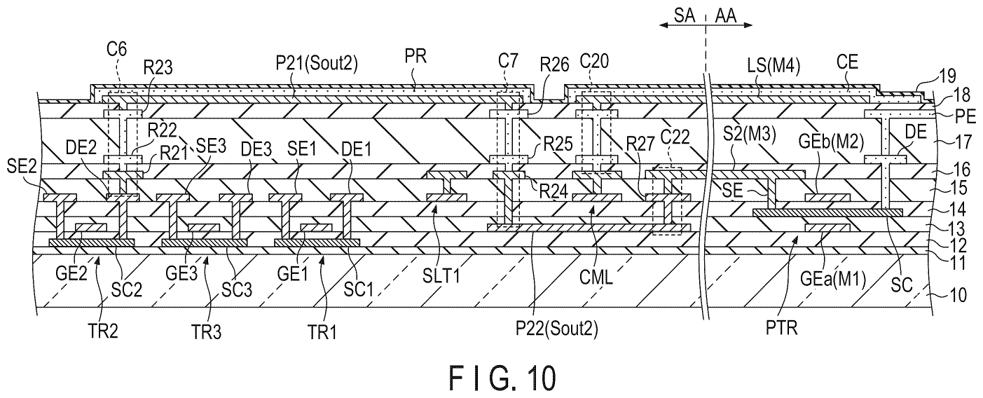

FIG. 10 is a schematic cross-sectional view showing the connection structure between the second transistor TR2 and the second signal line S2. The second output line Sout2 includes the first and second portions P21 and P22 shown in FIG. 7 as well.

The first portion P21 connected to the drain electrode DE2 in the contact portion C6 passes through the upper side of the first select line SLT1 and is connected to the second portion P22 in the contact portion C7. The first portion P21 is covered with a protective layer PR formed of the same conductive oxide as the common electrode CE.

In the example of FIG. 10, the contact portion C6 includes relay portions R21, R22 and R23. The relay portion R21 is provided on the insulating layer 15 and is covered with the insulating layer 16. Thus, the relay portion R21 is formed by the metal layer M3. The relay portion R22 is provided on the insulating layer 16 and is covered with the insulating layer 17. The relay portion R22 is formed of the same conductive oxide as the drain electrode DE. The relay portion R23 is provided on the insulating layer 17 and is covered with the insulating layer 18. The relay portion R23 is formed of the same conductive oxide as the pixel electrode PE.

In the example of FIG. 10, the contact portion C7 includes relay portions R24, R25 and R26. The relay portion R24 is provided on the insulating layer 15 and is covered with the insulating layer 16. Thus, the relay portion R24 is formed by the metal layer M3. The relay portion R25 is provided on the insulating layer 16 and is covered with the insulating layer 17. The relay portion R25 is formed of the same conductive oxide as the drain electrode DE. The relay portion R26 is provided on the insulating layer 17 and is covered with the insulating layer 18. The relay portion R26 is formed of the same conductive oxide as the pixel electrode PE.

The second portion P22 passes through the lower side of the common voltage line CML and is connected to the second signal line S2 in a contact portion C22. In the example of FIG. 10, the contact portion C22 includes a relay portion R27. The relay portion R27 is provided on the insulating layer 14 and is covered with the insulating layer 15. Thus, the relay portion R27 is formed by the metal layer M2.

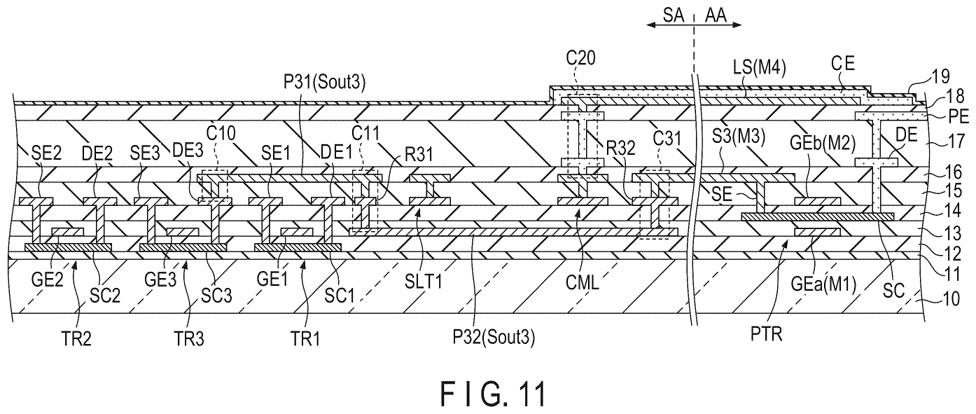

FIG. 11 is a schematic cross-sectional view showing the connection structure between the third transistor TR3 and the third signal line S3. The third output line Sout3 includes the first and second portions P31 and P32 shown in FIG. 8 as well.

The first portion P31 connected to the drain electrode DE3 in the contact portion C10 passes through the upper side of the first transistor TR1 and is connected to the second portion P32 in the contact portion C11. In the example of FIG. 11, the contact portion C11 includes a relay portion R31. The relay portion R31 is provided on the insulating layer 14 and is covered with the insulating layer 15. Thus, the relay portion R31 is formed by the metal layer M2.

The second portion P32 passes through the lower side of the first select line SLT1 and the common voltage line CML and is connected to the third signal line S3 in a contact portion C31. In the example of FIG. 11, the contact portion C31 includes a relay portion R32. The relay portion R32 is provided on the insulating layer 14 and is covered with the insulating layer 15. Thus, the relay portion R32 is formed by the metal layer M2.

The connection structure between the fourth transistor TR4 and the fourth signal line S4 is substantially the same as the connection structure between the second transistor TR2 and the second signal line S2 in FIG. 10. Specifically, the first portion P41 of the fourth output line Sout4 passes through the upper side of the first select line SLT1. The third portion P43 connected to the first portion P41 via the second portion P42 passes through the lower side of the common voltage line CML. The first portion P41 formed by the metal layer M4 is covered with a protective layer PR formed of a conductive oxide.

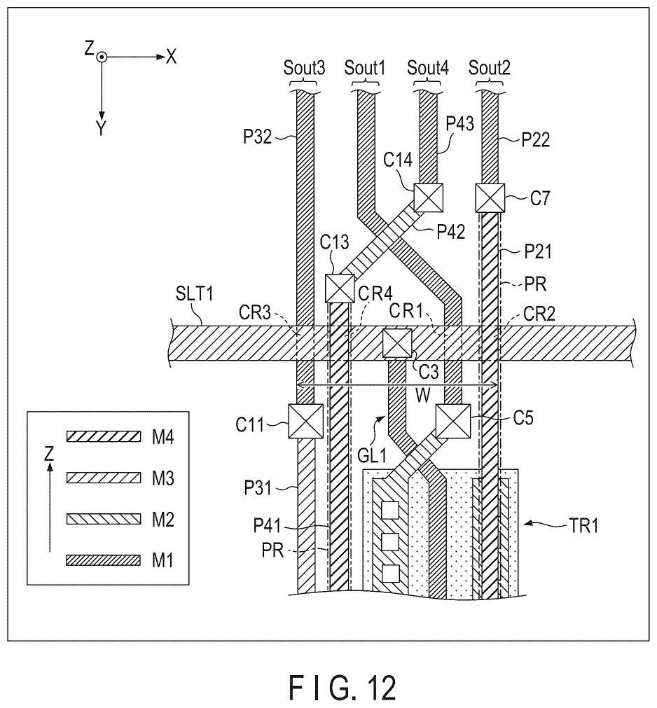

The configuration of the display device DSP of the embodiment described above can realize the efficient layout of the switch circuit ASW. An example of this effect is explained with reference to FIG. 12.

FIG. 12 is a schematic plan view in which the vicinity of the first select line SLT1 in FIG. 6 is enlarged. In the following explanation, of the first output line Sout1, a portion which intersects with the first select line SLT1 is called a first intersection CR1. Of the second output line Sout2, a portion which intersects with the first select line SLT1 is called a second intersection CR2. Of the third output line Sout3, a portion which intersects with the first select line SLT1 is called a third intersection CR3. Of the fourth output line Sout4, a portion which intersects with the first select line SLT1 is called a fourth intersection CR4.

The first intersection CR1 is part of the first signal line Sout1 formed by the metal layer M1. The second intersection CR2 is part of the first portion P21 formed by the metal layer M4. The third intersection CR3 is part of the second portion P32 formed by the metal layer M1. The fourth intersection CR4 is part of the first portion P41 formed by the metal layer M4. Thus, in the embodiment, two of the intersections CR1 to CR4 are formed by the metal layer M1, and the remaining two intersections are formed by the metal layer M4.

From another viewpoint, the first select line SLT1 is located between the intersections CR1 and CR3 and the intersections CR2 and CR4 in the third direction Z (the thickness direction of the array substrate AR). The intersections CR1 and CR3 are located under the insulating layer 17 formed of an organic insulating material. The intersections CR2 and CR4 are located above the insulating layer 17.

The contact portion C3 of the gate line GL1 and the first select line SLT1 is provided near the intersections CR1 to CR4. In the example of FIG. 12, the first intersection CR3, the fourth intersection CR4, the contact portion C3, the first intersection CR1 and the second intersection CR2 are arranged in this order in the first direction X. In the example of FIG. 12, the second portion P42 intersects with the first signal line Sout1. By this configuration, the third output line Sout3, the first output line Sout1, the fourth output line Sout4 and the second output line Sout2 are arranged in this order in the first direction X.

In a high-definition display device DSP, the pitch of subpixels SPR, SPG and SPB needs to be narrowed. To realize the narrowed pitch, the width of the switch circuit ASW also needs to be reduced. However, if all of the intersections CR1 to CR4 are formed by the same metal layer, width W of the group of lines consisting of the intersections CR1 to CR4 and the gate line GL1 cannot be sufficiently reduced because of the necessity to assure the insulating properties between the intersections CR1 to CR4 and the restriction of the processing ability of the manufacturing device. In this manner, the width of each circuit unit CU could be restricted.

To the contrary, in the embodiment, two of the intersections CR1 to CR4 are formed by the metal layer M1, and the remaining two intersections are formed by the metal layer M4. In this case, intersections formed by different layers can be provided so as to be close to each other or overlap each other. Thus, compared to a case where all of the intersections CR1 to CR4 are formed by the same metal layer, width W can be reduced. Consequently, the width of the switch circuit ASW can be reduced, and a high-definition display device DSP can be realized.

The metal layer M1 is a layer which forms the gate electrodes GEa and GE1 to GE4 of the transistors PTR and TR1 to TR4. The metal layer M4 is a layer which forms the light-shielding layer LS. When the intersections CR1 to CR4 are formed by using these metal layers M1 and M4, it is unnecessary to add a metal layer for the intersections CR1 to CR4. Thus, this configuration prevents the increase in the manufacturing cost of the display device DSP and also contributes to the reduction in the thickness of the display device DSP.

In the example of FIG. 12, both of the first portions P21 and P41 formed by the metal layer M4 are covered with the protective layer PR. By this configuration, the first portions P21 and P41 can be protected from etching at the time of processing the common electrode CE, etc.

The configuration of the display device DSP disclosed in the embodiment can be modified in various ways. For example, two of the intersections CR1 to CR4 may not be necessarily formed by the metal layer M1, and the remaining two intersections may not be necessarily formed by the metal layer M4. As another example, three of the intersections CR1 to CR4 may be formed by one of the metal layers M1 and M4, and the remaining intersection may be formed by the other one of the metal layers M1 and M4. At least one of the intersections CR1 to CR4 may be formed by a metal layer other than the metal layers M1 and M4.

The embodiment exemplarily shows a configuration in which NMOS transistors are used as the transistors TR1 to TR4. However, CMOS transistors may be used as the transistors TR1 to TR4. In this case, the transistors TR1 to TR4 each includes an N-type transistor and a P-type transistor.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. An array substrate comprising:
a plurality of signal lines provided in an active area; and
a switch circuit provided in a surrounding area around the active area and connected to the signal lines, wherein
the signal lines include a first signal line and a second signal line,
the switch circuit includes:
a circuit unit including a first transistor and a second transistor;
a first input line connected to the first transistor and the second transistor;
a first select line which is provided between the circuit unit and the active area and supplies a first select signal for turning the first transistor on;
a second select line which supplies a second select signal for turning the second transistor on;
a first output line which connects the first transistor and the first signal line to each other and intersects with the first select line; and
a second output line which connects the second transistor and the second signal line to each other and intersects with the first select line, and
a first intersection of the first output line which intersects with the first select line and a second intersection of the second output line which intersects with the first select line are formed in different layers.

2. The array substrate of claim 1, wherein
the first select line is located between the first intersection and the second intersection in a thickness direction of the array substrate.

3. The array substrate of claim 1, wherein
the first transistor includes:
a first semiconductor layer;
a first gate electrode which is connected to the first select line and intersects with the first semiconductor layer;
a first source electrode which connects the first input line and the first semiconductor layer to each other; and
a first drain electrode which connects the first semiconductor layer and the first output line to each other, and
the first intersection is formed in a same layer as the first gate electrode.

4. The array substrate of claim 3, wherein
the first select line includes a first layer formed in a same layer as the signal lines, and a second layer formed in a same layer as the first drain electrode.

5. The array substrate of claim 1, further comprising an insulating layer located above the first transistor, the second transistor and the first select line, and formed of an organic material, wherein
the second intersection is formed above the insulating layer.

6. The array substrate of claim 5, further comprising a conductive light-shielding layer which is provided in the active area and overlaps the signal lines, wherein
the second intersection is formed in a same layer as the light-shielding layer.

7. The array substrate of claim 6, wherein
the second intersection is covered with a protective layer formed of a conductive oxide.

8. The array substrate of claim 1, wherein
the first transistor and the second transistor are arranged in an extension direction of the signal lines.

9. The array substrate of claim 1, wherein
the signal lines further include a third signal line and a fourth signal line,
the circuit unit further includes:
a third transistor to which the first select signal is supplied from the first select line; and
a fourth transistor to which the second select signal is supplied from the second select line,
the switch circuit further includes:
a second input line connected to the third transistor and the fourth transistor;
a third output line which connects the third transistor and the third signal line to each other and intersects with the first select line; and
a fourth output line which connects the fourth transistor and the fourth signal line to each other and intersects with the first select line, and
a third intersection of the third output line which intersects with the first select line and a fourth intersection of the fourth output line which intersects with the first select line are formed in different layers.

10. The array substrate of claim 9, wherein
the first transistor, the second transistor, the third transistor and the fourth transistor are arranged in an extension direction of the signal lines.

11. A display device comprising an array substrate, wherein
the array substrate comprises:
a plurality of signal lines provided in an active area; and
a switch circuit provided in a surrounding area around the active area and connected to the signal lines,
the signal lines include a first signal line and a second signal line,
the switch circuit includes:
a circuit unit including a first transistor and a second transistor;
a first input line connected to the first transistor and the second transistor;
a first select line which is provided between the circuit unit and the active area and supplies a first select signal for turning the first transistor on;
a second select line which supplies a second select signal for turning the second transistor on;
a first output line which connects the first transistor and the first signal line to each other and intersects with the first select line; and
a second output line which connects the second transistor and the second signal line to each other and intersects with the first select line,
a first intersection of the first output line which intersects with the first select line and a second intersection of the second output line which intersects with the first select line are formed in different layers, and
the active area includes:
a plurality of pixel transistors connected to the signal lines; and
a plurality of pixel electrodes connected to the pixel transistors, respectively.

12. The display device of claim 11, further comprising:
a counter-substrate facing the array substrate; and
a liquid crystal layer provided between the array substrate and the counter-substrate.

13. The display device of claim 11, wherein
the first select line is located between the first intersection and the second intersection in a thickness direction of the array substrate.

14. The display device of claim 11, wherein
the first transistor includes:
a first semiconductor layer;
a first gate electrode which is connected to the first select line and intersects with the first semiconductor layer;
a first source electrode which connects the first input line and the first semiconductor layer to each other; and
a first drain electrode which connects the first semiconductor layer and the first output line to each other, and
the first intersection is formed in a same layer as the first gate electrode.

15. The display device of claim 14, wherein
the first select line includes a first layer formed in a same layer as the signal lines, and a second layer formed in a same layer as the first drain electrode.

16. The display device of claim 11, further comprising an insulating layer located above the first transistor, the second transistor and the first select line and formed of an organic material, and
the second intersection is formed above the insulating layer.

17. The display device of claim 16, further comprising a conductive light-shielding layer which is provided in the active area and overlaps the signal lines, wherein
the second intersection is formed in a same layer as the light-shielding layer.

18. The display device of claim 17, wherein
the second intersection is covered with a protective layer formed of a conductive oxide.

19. The display device of claim 11, wherein
the first transistor and the second transistor are arranged in an extension direction of the signal lines.

20. The display device of claim 11, wherein
the signal lines further include a third signal line and a fourth signal line,
the circuit unit further includes:
a third transistor to which the first select signal is supplied from the first select line; and
a fourth transistor to which the second select signal is supplied from the second select line,
the switch circuit further includes:
a second input line connected to a third transistor and a fourth transistor;
a third output line which connects the third transistor and the third signal line to each other and intersects with the first select line; and
a fourth output line which connects the fourth transistor and the fourth signal line to each other and intersects with the first select line, and
a third intersection of the third output line which intersects with the first select line and a fourth intersection of the fourth output line which intersects with the first select line are formed in different layers.
